(19) United States
(12) Patent Application Publication
(10) Pub. No.: US 2025/0323069 A1
(43) Pub. Date: Oct. 16, 2025

(54) PLANARIZING METHOD, PLANARIZING APPARATUS, AND ARTICLE MANUFACTURING METHOD

(71) Applicant: CANON KABUSHIKI KAISHA, Tokyo (JP)

(72) Inventor: YOSUKE MURAKAMI, Tochigi (JP)

(21) Appl. No.: 19/173,217

(22) Filed: Apr. 8, 2025

(30) Foreign Application Priority Data
Apr. 11, 2024 (JP) 2024-064118

(51) Int. Cl. H01L 21/67; H01L 21/304; H01L 21/68

(52) U.S. Cl. CPC H01L 21/67092; H01L 21/304; H01L 21/67253; H01L 21/67259; H01L 21/68

(57) ABSTRACT

A planarizing method includes forming a first planarizing layer on a substrate by molding a curable composition using a first planarizing member, forming a second planarizing layer on the first planarizing layer by molding the curable composition using a second planarizing member, and determining, based on information representing performance of each of at least two planarizing members, a planarizing member to be used as the first planarizing member and a planarizing member to be used as the second planarizing member.

### BACKGROUND

### Technical Field

The present disclosure relates to a planarizing method, a planarizing apparatus, and an article manufacturing method.

### Description of the Related Art

There is known a planarization technique for planarizing a step of a substrate by forming a coating film on the substrate using a coating device such as a spin coater. However, such planarization technique is insufficient to planarize the step of the substrate on a nanoscale. Thus, it is proposed to planarize the substrate using the imprint technique. Japanese Patent Laid-Open No. 2011-529626 describes that a curable composition is dropped on a substrate in consideration of the step of the substrate and the curable composition is cured in a state in which the flat surface of a plate is in contact with the dropped curable composition, thereby forming a film having a flat surface. Japanese Patent Laid-Open No. 2020-4920 describes that a mold is cleaned to remove a composition adhering to the mold used for planarization.

A planarizing member as a member that is brought into contact with a curable composition to form a planarizing film needs to have a flat surface but the surface of the planarizing member may be scratched or have a foreign substance adhered thereto. In addition, when performing a planarizing process, a part of the curable composition may peel off to adhere to the planarizing member. If the surface of the planarizing member is not flat, the shape is transferred to a planarizing layer to be formed, thereby decreasing the flatness. This may cause a defect in an exposure process after planarization, thereby lowering the yield.

### SUMMARY

The present disclosure provides a technique of reducing the influence of a defect of a planarizing member.

One aspect of the present disclosure provides a planarizing method comprising: forming a first planarizing layer on a substrate by molding a curable composition using a first planarizing member; forming a second planarizing layer on the first planarizing layer by molding the curable composition using a second planarizing member; and determining, based on information representing performance of each of at least two planarizing members, a planarizing member to be used as the first planarizing member and a planarizing member to be used as the second planarizing member.

Further features of the present disclosure will become apparent from the following description of exemplary embodiments with reference to the attached drawings.

### BRIEF DESCRIPTION OF THE DRAWINGS

FIG. 1 is a view schematically showing the configuration of a planarizing apparatus according to the first embodiment;

FIGS. 2A to 2F are views schematically showing the procedure of a planarizing method according to the first embodiment;

FIGS. 3A and 3B are views each schematically showing a planarizing step in a case where a planarizing member has a defect;

FIGS. 4A and 4B are flowcharts illustrating the planarizing method executed by the planarizing apparatus according to the first embodiment;

FIG. 5 is a view schematically showing the configuration of a planarizing apparatus according to the second embodiment;

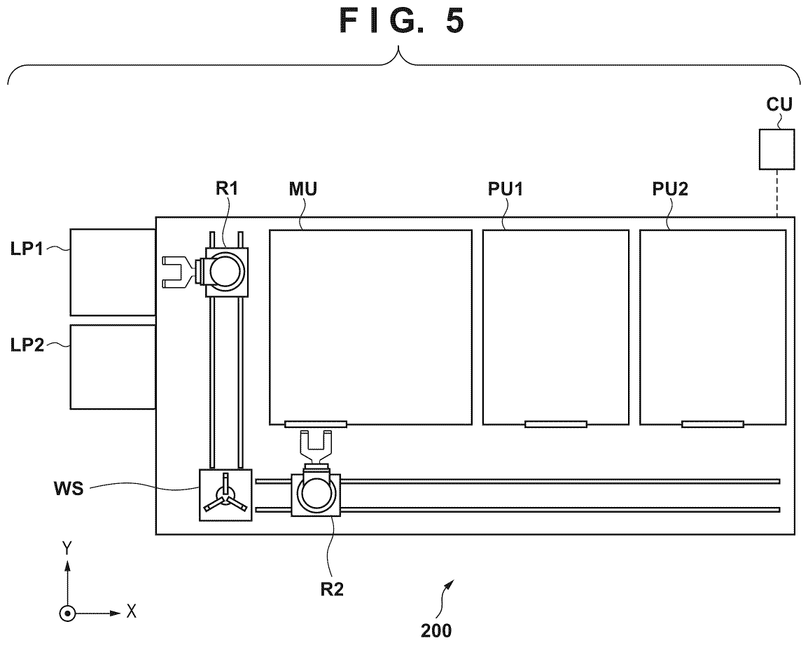

FIGS. 6A and 6B are views respectively, schematically showing the configurations of an application unit and a planarizing unit of the planarizing apparatus according to the second embodiment; and

FIGS. 7A to 7C are flowchart illustrating a planarizing method executed by the planarizing apparatus according to the second embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an embodiment that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are 6X, 6Y, and 6Z, respectively. Control or driving concerning the X-axis, the Y-axis, and the Z-axis means control or driving concerning a direction parallel to the X-axis, a direction parallel to the Y-axis, and a direction parallel to the Z-axis, respectively.

### First Embodiment

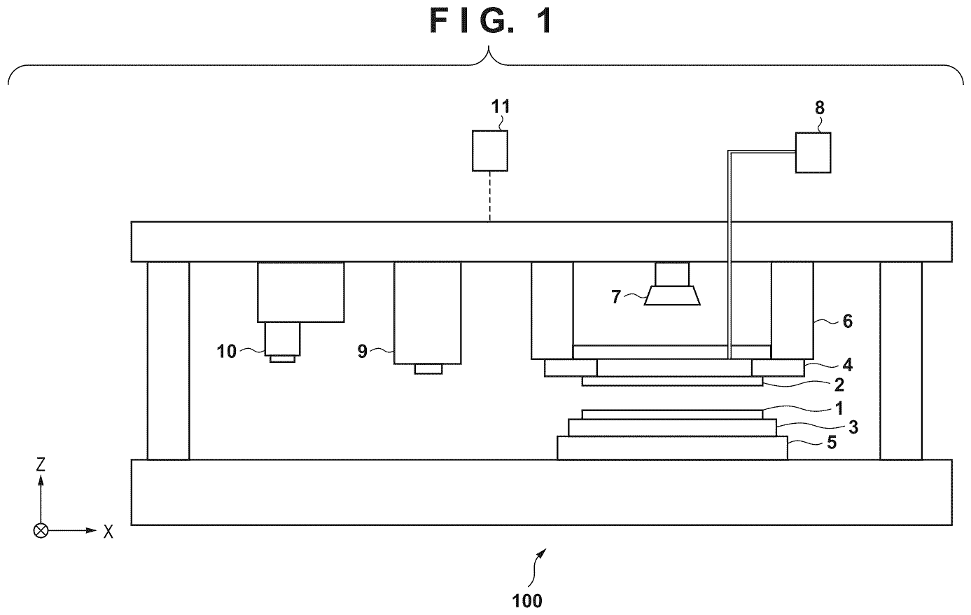

FIG. 1 is a schematic view showing a planarizing apparatus 100 according to the first embodiment. The planarizing apparatus 100 is used to form a planarizing layer on a substrate 1 in order to prevent a defect from being generated in an article such as a semiconductor device in manufacturing the article. The forming process of one planarizing layer in a planarizing method executed using the planarizing apparatus 100 can include the following steps.
(a) An application step of applying a planarizing material such as a curable composition onto the substrate 1
(b) A contact step of bringing a planarizing member 2 into contact with the planarizing material applied onto the substrate 1
(c) A curing step of curing the planarizing material by applying curing energy to the planarizing material and forming a planarizing layer
(d) A separation step of separating the planarizing member 2 from the planarizing layer on the substrate 1

The planarizing material is molded by curing the planarizing material in a state in which the planarizing material and the planarizing member 2 are in contact with each other, thereby forming the planarizing layer made from the cured product of the planarizing material. With the planarizing process, the unevenness on the substrate 1 is covered with the planarizing layer. The surface of the planarizing layer is a flat surface conforming to the flat surface of the planarizing member 2. As the planarizing material, a curable composition to be cured by receiving curing energy is used. As the curing energy, for example, heat or light such as ultraviolet light can be used.

This embodiment will describe an example in which a photo-curable resin to be cured by light irradiation is used as the curable composition. The photo-curable resin contains at least a plurality of polymerizable compounds and a photopolymerization initiator for generating a polymerizing factor by reacting with a predetermined wavelength. Irradiating the planarizing material with light that causes a curing reaction in the curable composition will be referred to as “exposure” hereinafter.

The planarizing apparatus 100 shown in FIG. 1 can include a substrate holder 3, a substrate driver 5, a planarizing member holder 4, a planarizing member driver 6, a curing unit 7, a pressure adjuster 8, an application unit 9, an alignment unit 10, and a controller 11.

The substrate 1 can be, for example, a semiconductor wafer or MEMS wafer on which a pattern is formed. The substrate 1 may be a wafer for manufacturing a power semiconductor, a glass substrate for manufacturing a display, or a substrate for manufacturing a device such as a bio-element. The substrate 1 may have a plurality of layers on the base material. As the base material, for example, a semiconductor, glass, a ceramic, a metal, a resin, or the like can be used. The substrate 1 may be provided with an adhesive layer, as needed, to improve the adhesion between the planarizing material and the substrate 1.

The planarizing member 2 can have, for example, the same outer shape as that of the substrate 1. The planarizing member 2 can be made of a material, such as quartz, that can transmit ultraviolet light. The substrate holder 3 is configured to hold the substrate 1, and can hold, by a vacuum suction force or an electrostatic force, the substrate 1 loaded by a conveyance apparatus (not shown) or the like. The planarizing member holder 4 is configured to hold the planarizing member 2, and holds, by a vacuum suction force or an electrostatic force, the planarizing member 2 loaded by a conveyance apparatus (not shown) or the like.

The substrate driver 5 is configured to move the substrate holder 3 in the X and Y directions. The substrate driver 5 includes an actuator such as a linear motor. The substrate driver 5 can include a measurement device such as a laser interferometer or an encoder for measuring a position. By moving the substrate holder 3 holding the substrate 1 in the X and Y directions, the substrate 1 can be arranged immediately below the planarizing member 2 in the Z direction or immediately below the application unit 9 in the Z direction.

The planarizing member driver 6 can be configured to move the planarizing member 2 in the Z direction. The planarizing member driver 6 can include, for example, an actuator such as a linear motor or an air cylinder. By controlling the distance between the substrate 1 and the planarizing member 2 by the planarizing member driver 6, it is possible to bring the planarizing member into contact with the substrate 1 or separate the planarizing member from the substrate 1. The planarizing member driver 6 may further drive the planarizing member holder 4 with respect to the 6X-axis and 6Y-axis, thereby making it possible to adjust the parallelism between the substrate 1 and the planarizing member 2.

The curing unit 7 is configured to irradiate the planarizing material with curing energy (for example, light such as ultraviolet light). The curing unit 7 includes a light source that generates light for curing the planarizing material. Furthermore, the curing unit 7 may include an optical element for adjusting light emitted from the light source to light suitable for planarization. The light emitted from the curing unit 7 passes through the planarizing member to enter the planarizing material on the substrate 1, thereby curing the planarizing material.

The pressure adjuster 8 can be configured to adjust the pressure in a space on the back surface (the surface not facing the substrate 1) of the planarizing member 2. The pressure adjuster 8 can include, for example, an air regulator, a pressure pump, and a decompression pump. By adjusting the pressure in the space, the planarizing member 2 can be bent in the Z direction. For example, when pressing the planarizing member 2 against the substrate 1, the planarizing member 2 can be bent into a convex shape toward the substrate 1. This is advantageous in gradually bringing the planarizing member 2 into contact with the planarizing material from the center of the planarizing member 2 to the outer periphery so as not to take air into the planarizing material between the planarizing member 2 and the substrate 1. In an example, after the planarizing member 2 completely contacts the planarizing material on the substrate 1, the pressure on the back surface of the planarizing member 2 can be released.

The application unit 9 can be configured to, for example, apply the planarizing material to the substrate 1 by an inkjet method. Note that the term “apply” is used as, for example, a term including a form in which a film of the planarizing material is formed on the substrate 1 and a form in which droplets of the planarizing material are discretely arranged. The application unit 9 can include, for example, an inkjet head and a tank that supplies the planarizing material. By dropping the planarizing material on the substrate 1 by the application unit 9 while moving the substrate 1 by the substrate driver 5, it is possible to apply the planarizing material to the substrate 1 to have a desired distribution.

The alignment unit 10 can be configured to detect an alignment mark of the substrate 1. The alignment unit 10 can include, for example, an illumination unit, an optical system, and a camera. The alignment unit 10 can detect the alignment mark of the substrate 1 held by the substrate holder 3. This can improve the accuracy of alignment between the substrate 1 and the planarizing member 2 and the application position of the planarizing material on the substrate 1.

The controller 11 can be configured to control the above-described components of the planarizing apparatus 100. The controller 11 can be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer installed with a program, or a combination of all or some of them.

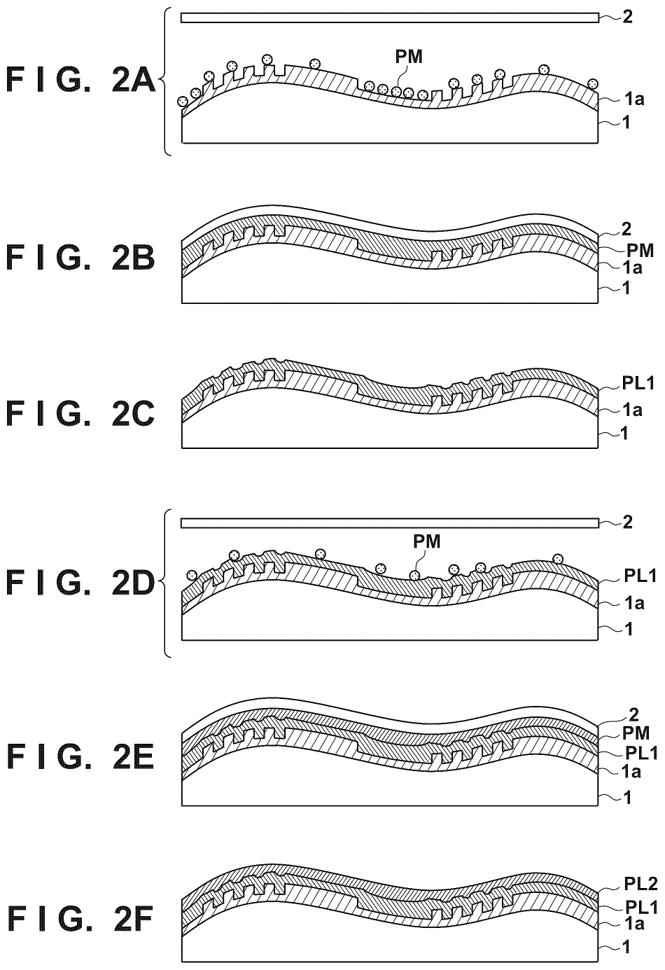

A planarizing method executed by the planarizing apparatus 100 will be exemplarily described next with reference to FIGS. 2A to 2F. In general, in this planarizing method, the first planarizing layer is formed on a substrate by molding the curable composition using the first planarizing member, and the second planarizing layer is formed on the first planarizing layer by molding the curable composition using the second planarizing member.

First, the application unit 9 applies a planarizing material PM to the substrate 1 having an underlying pattern 1a (first application step). FIG. 2A schematically shows a state after the planarizing material PM is arranged on the substrate 1 and before the planarizing member 2 is brought into contact with the planarizing material PM. The planarizing material PM can be applied onto the substrate 1 by the inkjet method. As schematically shown in FIG. 2A, droplets of the planarizing material PM can be arranged on the substrate 1. The density distribution of the droplets can be determined in accordance with the unevenness on the underlying pattern 1a.

Next, the planarizing member 2 is operated so as to bring the planarizing material PM on the substrate 1 and the planarizing member 2 into contact with each other (first contact step). The planarizing member 2 is pressed against the planarizing material PM, and thus the planarizing material PM can spread over the entire surface of the substrate 1. FIG. 2B shows a state in which the entire planarizing surface (the surface brought into contact with the planarizing material) of the planarizing member 2 contacts the planarizing material PM on the substrate 1 and the planarizing member 2 conforms to low-frequency components among the spatial frequency components of the surface shape of the substrate 1. In this state, the planarizing material PM is exposed by the curing unit 7 and is then cured, thereby forming a first planarizing layer PL1 (first curing step). After that, the planarizing member 2 is separated from the first planarizing layer PL1 on the substrate 1 (first separation step). The above step, that is, the step of applying the planarizing material PM onto the underlying pattern 1a, bringing the planarizing member 2 into contact with the planarizing material PM, forming the first planarizing layer PL1 by curing the planarizing material PM, and separating the planarizing member 2 from the first planarizing layer PL1 is the first planarizing step.

FIG. 2C shows a structure formed from the first planarizing layer PL1 and the substrate 1 after the planarizing member 2 is separated from the first planarizing layer PL1. The flatness of the surface of the first planarizing layer PL1 is improved more than the surface of the underlying pattern 1a. However, when the planarizing material PM is cured, the planarizing material PM shrinks in the thickness direction due to curing shrinkage, and thus the surface of the first planarizing layer PL1 is not perfectly flat.

To cope with this, the application unit 9 further applies the planarizing material PM onto the first planarizing layer formed in the first planarizing step (second application step). FIG. 2D shows a state in which the planarizing material PM is further supplied onto the first planarizing layer PL1. The application amount and the application distribution of the planarizing material PM can be different from those at the time of forming the first planarizing layer PL1. In the second application step, the planarizing material that is enough to form a flat surface on the unevenness on the surface of the first planarizing layer PL1 is applied.

Next, the planarizing member 2 is operated so as to bring the planarizing material PM and the planarizing member 2 into contact with each other (second contact step). FIG. 2E shows a state in which the planarizing member 2 is pressed against the planarizing material PM, the entire planarizing surface of the planarizing member 2 contacts the planarizing material PM, and the planarizing member 2 conforms to low-frequency components among the spatial frequency components of the surface of the first planarizing layer PL1. In this state, the planarizing material PM is exposed by the curing unit 7 and is then cured, thereby forming a second planarizing layer PL2 (second curing step). After that, the planarizing member 2 is separated from the second planarizing layer PL2 on the substrate 1 (second separation step). The step of applying the planarizing material PM onto the first planarizing layer PL1, bringing the planarizing member 2 into contact with the planarizing material PM, forming the second planarizing layer PL2 by curing the planarizing material PM, and separating the planarizing member 2 from the second planarizing layer PL2 is the second planarizing step.

FIG. 2F shows a structure formed from the substrate 1, the first planarizing layer PL1, and the second planarizing layer PL2 after the planarizing member 2 is separated from the second planarizing layer PL2. When the second planarizing layer PL2 is formed on the first planarizing layer PL1, the flatness is improved, as compared with a case where only the first planarizing layer PL1 is formed.

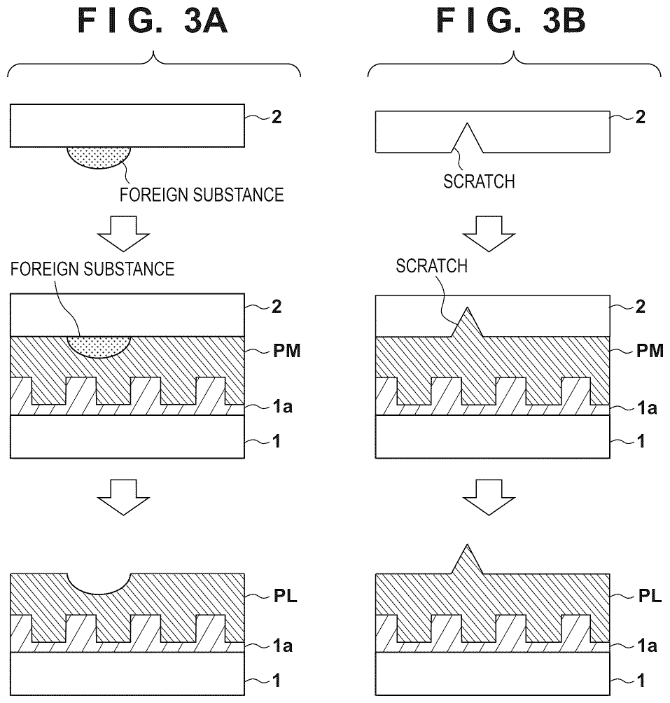

As described above, it is possible to form the planarizing layer (the first planarizing layer PL1 or the second planarizing layer PL2) on the substrate 1, but the surface of the planarizing member 2 may have a foreign substance adhered thereto or may be scratched for some reason. If a foreign substance adheres to the planarizing member 2, the shape of the foreign substance can be transferred to a planarizing layer PL on the substrate 1, as shown in FIG. 3A. If the planarizing member 2 is scratched, the shape of the scratch is transferred to the planarizing layer PL on the substrate 1, as shown in FIG. 3B. In either of the cases shown in FIGS. 3A and 3B, the flatness of the planarizing layer PL decreases. Such planarizing layer PL may have an adverse effect, for example, lowering the quality of an image formed on a photoresist film on the substrate 1 in an exposure step executed by an exposure apparatus, thereby lowering the manufacturing yield of the article.

To avoid this, it is necessary to use the planarizing member 2 having a planarizing surface (the surface brought into contact with the planarizing material PM) that is flat enough. However, by repeatedly using the planarizing member 2, the planarizing member 2 may be scratched or have a foreign substance adhered thereto. To cope with this, in the planarizing apparatus 100 or the planarizing method according to the first embodiment, the use of the planarizing member 2 is controlled to decrease the influence of the scratch or adhesion of the foreign substance of the planarizing member 2. The unevenness such as the scratch and the foreign substance on the surface of the planarizing member 2 will be referred to as a “surface defect” hereinafter.

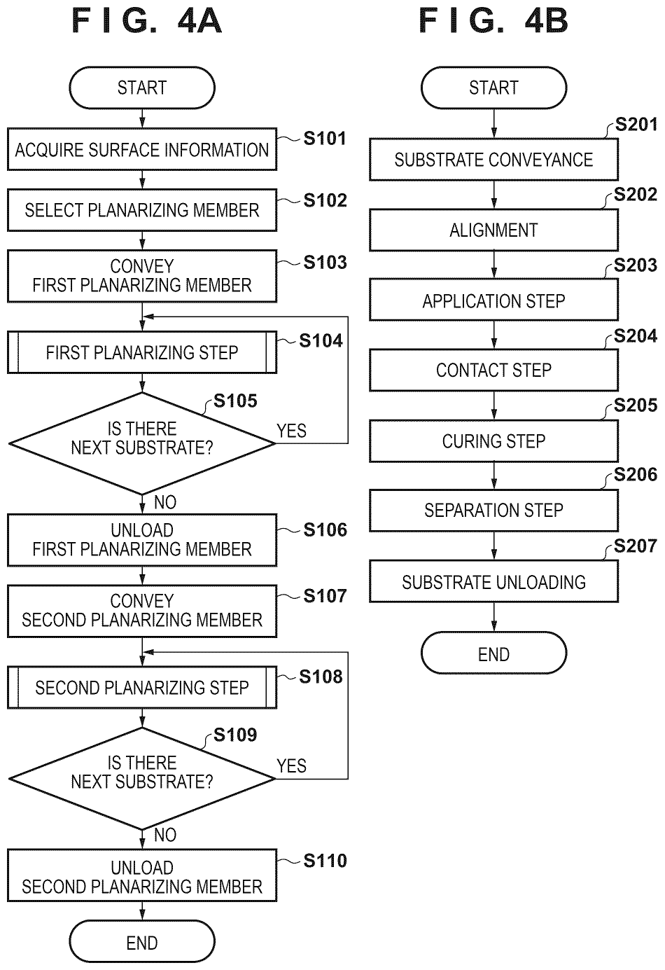

FIG. 4A is a flowchart illustrating the procedure of the planarizing method executed by the planarizing apparatus 100 according to the first embodiment. In this example, the controller 11 controls the processing procedure of a plurality of substrates so as to form the first planarizing layer on each of the plurality of substrates and then form the second planarizing layer on each of the plurality of substrates.

In step S101, the controller 11 acquires surface information of each of the plurality of planarizing members 2 (or at least two planarizing members 2). The surface information is information representing the performance of the planarizing member 2. The surface information is, for example, information concerning a defect on the planarizing surface (the surface brought into contact with the planarizing material (curable composition)) of the planarizing member 2. The surface information may be, for example, information representing a result of measuring the surface defect of the planarizing member 2 using a defect inspection apparatus or the like outside the planarizing apparatus 100.

Alternatively, the surface information may be acquired by performing, in advance, a planarizing process for a flat test substrate (normally called a bare silicon wafer) utilizing the fact that the unevenness of the planarizing member 2 will be transferred, and performing defect inspection of the formed planarizing layer. In this case, for example, inspection can be performed using a plurality of test substrates, and a common defect in the inspection results can be obtained as defect information. The common defect is a defect that is repeatedly generated at identical positions on the plurality of substrates. Alternatively, the surface information may be generated by counting, by the controller 11, the use count of the planarizing member and performing estimation based on the use count. For example, by assuming that surface defects increase at a rate of one per 100 uses, the number of surface defects of the planarizing member 2 can be given by use count×0.01. The use count for generating one surface defect can depend on a process condition, the cleanliness of the substrate, and the like, and is thus determined based on the actual results. The method of generating the surface information by estimation based on the use count is simple but is advantageous in terms of productivity because an external inspection apparatus is not used.

Alternatively, the surface information may be information concerning the manufacturing grade of the planarizing member 2. This is based on the assumption that the number of surface defects is small for a high-quality manufacturing grade. The manufacturer of the planarizing member 2 may set the manufacturing grade in accordance with the flatness and the polishing level of the planarizing member 2.

Alternatively, the surface information may be information concerning the coating film of the planarizing member 2 (for example, the presence/absence of a coating film, a type of a coating film, a material, or a grade). For example, the surface state of the planarizing member 2 having a coating film can be estimated to be good. This is because the unevenness on the surface of the planarizing member 2 is reduced by providing the coating film and/or adhesion of a foreign substance is suppressed by the coating film.

The controller 11 can acquire the surface information of the planarizing member 2 by the above-described method. The surface information can include information from which at least the number of surface defects is known.

Furthermore, the surface information preferably includes information concerning a surface defect size and a surface defect position.

In step S102, based on the performance of each of the at least two planarizing members 2, the controller 11 determines the planarizing member 2 to be used as the first planarizing member in the first planarizing step and the planarizing member 2 to be used as the second planarizing member in the second planarizing step (determination step). For example, based on the surface information acquired in step S101, the controller 11 can determine to use, as the second planarizing member, the planarizing member 2 having performance satisfying a predetermined criterion for use in the second planarizing step.

Furthermore, based on the surface information acquired in step S101, the controller 11 can determine to use, as the first planarizing member, the planarizing member 2 having performance not satisfying the predetermined criterion.

Alternatively, for example, if there is no shortage of the planarizing members 2 satisfying the predetermined criterion, the controller 11 may determine to use, as the first planarizing member, the planarizing member 2 satisfying the predetermined criterion. That is, based on the surface information acquired in step S101, the controller 11 can determine to use, as the first planarizing member, either the planarizing member 2 satisfying the predetermined criterion or the planarizing member 2 not satisfying the predetermined criterion. In other words, the controller 11 can determine to use the planarizing member 2 as the first planarizing member regardless of whether the planarizing member 2 satisfies the predetermined criterion.

Alternatively, the predetermined criterion can be a criterion concerning the number of defects of the planarizing surface. More specifically, the predetermined criterion can be a criterion that the number of defects of the planarizing surface is equal to or smaller than the first number. Alternatively, the predetermined criterion can be a criterion that the number of defects each having a size equal to or larger than the first size among the defects of the planarizing surface is equal to or smaller than the first number. Alternatively, the predetermined criterion can be a criterion that among the defects of the planarizing surface, the number of defects each existing at a position influencing the manufacturing yield of the article and each having a size equal to or larger than the first size is equal to or smaller than the first number. A position influencing the manufacturing yield of the article is typically a position in an effective chip region, and a position not influencing the manufacturing yield of the article is typically a position having no alignment mark in a scribe line region.

Furthermore, a lower criterion (a criterion lower than the predetermined criterion) which the first planarizing member used in the first planarizing step should satisfy may be determined. In this case, in step S102, the controller 11 may determine to use, as the first planarizing member, the planarizing member 2 having performance not satisfying the predetermined criterion but satisfying the lower criterion. The lower criterion can be a criterion that the number of defects of the planarizing surface is equal to smaller than the second number larger than the first number. Alternatively, the lower criterion can be a criterion that the number of defects each having a size equal to or larger than the second size larger than the first size among the defects of the planarizing surface is equal to or smaller than the second number. Alternatively, the lower criterion can be a criterion that among the defects of the planarizing surface, the number of defects each existing at a position influencing the manufacturing yield of the article and each having a size equal to or larger than the second size is equal to or smaller than the second number.

If all the planarizing members 2 usable in the planarizing method satisfy the predetermined criterion, in the determination step, it can be determined to use, as the first planarizing member, the planarizing member 2 having a relatively large number of defects and to use, as the second planarizing member, the planarizing member 2 having a relatively small number of defects. From another viewpoint, in a status in which the first planarizing member and the second planarizing member are to be determined from the limited number of planarizing members 2, in the determination step, the first planarizing member and the second planarizing member can be determined so that the performance of the second planarizing member is superior to the performance of the first planarizing member. For example, the controller 11 may divide the plurality of usable planarizing members 2 into a group used as the first planarizing member and a group used as the second planarizing member in accordance with the performance of each of the planarizing members 2 (for example, the number of defects of each of the planarizing members 2).

In step S103, the controller 11 controls the conveyance apparatus (not shown) to convey, to the planarizing member holder 4, the planarizing member 2 determined as the first planarizing member in step S102, thereby causing the planarizing member holder 4 to hold the planarizing member 2. In step S104, the controller 11 controls the respective components of the planarizing apparatus 100 to perform the first planarizing step. The first planarizing step can include steps S201 to S207 shown in a flowchart of FIG. 4B.

In step S201, the controller 11 controls the conveyance apparatus (not shown) to convey the substrate 1 to the substrate holder 3, thereby causing the substrate holder 3 to hold the substrate 1. In step S202, the controller 11 aligns the substrate 1 by observing the alignment mark on the substrate 1 using the alignment unit 10. This alignment is performed to prevent displacement of the application position of the planarizing material in step S203.

In step S203, the controller 11 controls the application unit 9 and the substrate driver 5 to apply the planarizing material onto the substrate 1 by the application unit 9. The application amount of the planarizing material can be adjusted in plane of the substrate 1 based on the density distribution of the unevenness on the substrate 1 and the like. In step S204, the controller 11 controls the planarizing member driver 6 to drive the planarizing member 2 in the −Z direction, thereby pressing the planarizing member 2 against the planarizing material on the substrate 1 to contact each other. As described above, at this time, the pressure adjuster deforms the planarizing member 2 into a convex shape toward the substrate 1, and the contact region between the planarizing member 2 and the planarizing material on the substrate 1 can gradually spread from the center to the outer periphery.

In step S205, the controller 11 controls the curing unit 7 to irradiate the planarizing material with light, thereby curing the planarizing material. In step S206, the controller 11 controls the planarizing member driver 6 to drive the planarizing member 2 in the +Z direction, and separates the planarizing member 2 from the planarizing material. In step S207, the controller 11 controls the conveyance apparatus (not shown) to unload the substrate 1.

In step S105, the controller 11 determines whether there is the substrate 1 to be processed next. If there is the substrate 1 to be processed next, the controller 11 executes step S104 for the substrate 1. If there is no substrate 1 to be processed next, the controller 11 advances to step S106. In step S106, the controller 11 controls the conveyance apparatus (not shown) to unload the planarizing member 2 as the first planarizing member from the planarizing member holder 4.

In step S107, the controller 11 controls the conveyance apparatus (not shown) to convey, to the planarizing member holder 4, the planarizing member 2 determined as the second planarizing member in step S102, thereby causing the planarizing member holder 4 to hold the planarizing member 2. In step S108, the controller 11 controls the respective components of the planarizing apparatus 100 to perform the second planarizing step. The second planarizing step can include steps S201 to S207.

In step S109, the controller 11 determines whether there is the substrate 1 to be processed next. If there is the substrate 1 to be processed next, the controller 11 executes step S108 for the substrate 1. If there is no substrate 1 to be processed next, the controller 11 advances to step S110. In step S110, the controller 11 controls the conveyance apparatus (not shown) to unload the planarizing member 2 as the second planarizing member from the planarizing member holder 4.

As described above, by determining the planarizing member 2 satisfying the predetermined criterion as the second planarizing member used in the second planarizing step, it is possible to obtain a planarizing film having a flatter surface. Furthermore, by using, as the first planarizing member for forming the planarizing layer on the lower side, the planarizing member 2 which no longer satisfies the predetermined criterion, it is possible to reduce cost of preparing the planarizing member 2.

Note that one or a plurality of planarizing steps may further be performed before the first planarizing step. That is, the planarizing method according to this embodiment may include three or more planarizing steps including the first planarizing step and the second planarizing step, and may stack three or more planarizing layers including the first planarizing layer and the second planarizing layer. In this case, it is preferable to form the planarizing layer on the upper side using the planarizing member 2 having a smaller number of defects.

### Second Embodiment

A planarizing apparatus and a planarizing method according to the second embodiment will be described below. Matters not mentioned as the second embodiment can comply with the first embodiment. A planarizing apparatus 200 according to the second embodiment includes a plurality of planarizing units. The planarizing apparatus 200 can include, for example, a first planarizing unit PU1 and a second planarizing unit PU2 as the plurality of planarizing units. In addition, the planarizing apparatus 200 can include an application unit MU, a substrate conveyance robot R1, a substrate conveyance robot R2, a substrate transfer machine WS, a substrate load port LP1, a substrate load port LP2, and a controller CU.

The planarizing units PU1 and PU2 may be equivalent units. The productivity is improved when the planarizing units PU1 and PU2 simultaneously perform planarizing processes. The application unit MU is a unit that applies a planarizing material to a substrate. The substrate load ports LP1 and LP2 are ports each for loading a substrate to the planarizing apparatus 200. A substrate cassette (not shown) that stores a substrate can be placed on each of the substrate load ports LP1 and LP2. By providing the plurality of substrate load ports, a wait time when replacing the substrate cassette is reduced. The substrate conveyance robot R1 extracts the substrate from the substrate cassette placed on each of the substrate load ports LP1 and LP2 and transfers it to the substrate transfer machine WS. The substrate conveyance robot R2 conveys, to each unit, the substrate transferred to the substrate transfer machine WS. The controller CU controls the respective components of the planarizing apparatus 200. The substrate conveyance robot R1, the substrate conveyance robot R2, and the substrate transfer machine WS (to be collectively referred to as a conveyance mechanism hereinafter) can be configured to convey a planarizing member 2 in addition to the substrate.

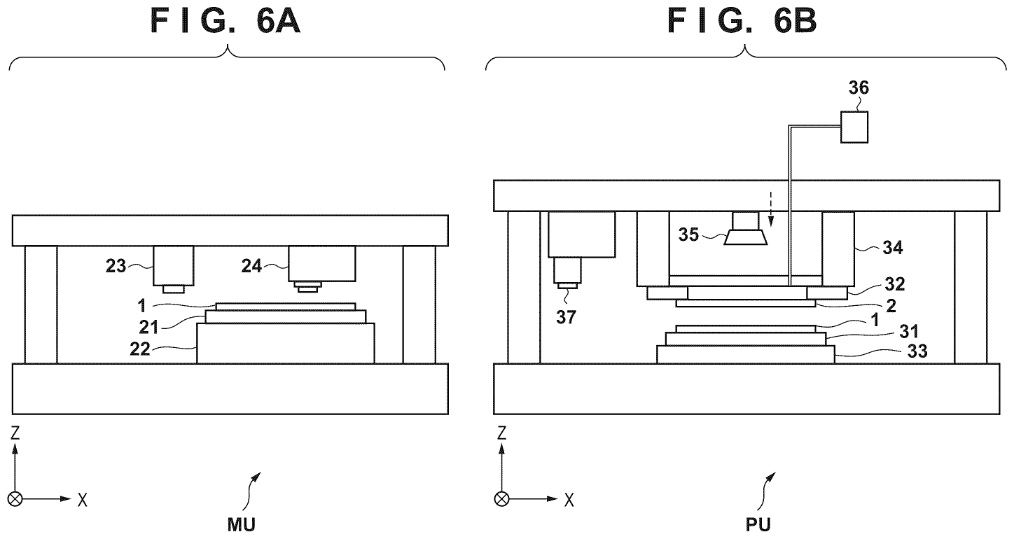

FIG. 6A is a view showing the configuration of the application unit MU. For example, the application unit MU applies the planarizing material onto a substrate 1 by the inkjet method. The application unit MU can include, for example, a substrate holder 21 that holds the substrate 1, a substrate driver 22 that drives the substrate holder 21, an application unit 23 that applies the planarizing material to the substrate 1, and an alignment unit 24 that measures the position of the substrate 1.

The substrate holder 21 holds the substrate 1 by a vacuum suction force or an electrostatic force. The substrate driver 22 can be configured to move the substrate 1 in the X and Y directions. The substrate driver 22 includes, for example, an actuator such as a linear motor. The substrate driver 22 can include a measurement device such as a laser interferometer or an encoder for measuring a position.

The application unit 23 can be configured to, for example, apply the planarizing material to the substrate 1 by the inkjet method. The application unit 23 can include, for example, an inkjet head and a tank that supplies the planarizing material. By dropping the planarizing material on the substrate 1 by the application unit 23 while moving the substrate 1 by the substrate driver 22, it is possible to apply the planarizing material to the substrate 1 to have a desired distribution.

The alignment unit 24 can be configured to detect an alignment mark of the substrate 1. The alignment unit 24 can include, for example, an illumination unit, an optical system, and a camera. The alignment unit 24 can detect the alignment mark of the substrate 1 held by the substrate holder 21. This can improve the accuracy of alignment between the substrate 1 and the planarizing member 2 and the application position of the planarizing material on the substrate 1.

The controller CU can be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer installed with a program, or a combination of all or some of them.

FIG. 6B shows the configuration of the planarizing unit PU. The planarizing unit PU can include a substrate holder 31 that holds the substrate 1, a planarizing member holder 32 that holds the planarizing member 2, a substrate driver 33, a planarizing member driver 34, a curing unit 35, a pressure adjuster 36, and an alignment unit 37. These units have the same functions as those of the substrate holder 3, the planarizing member holder 4, the substrate driver 5, the planarizing member driver 6, the curing unit 7, the pressure adjuster 8, and the alignment unit 10 of the first embodiment, respectively.

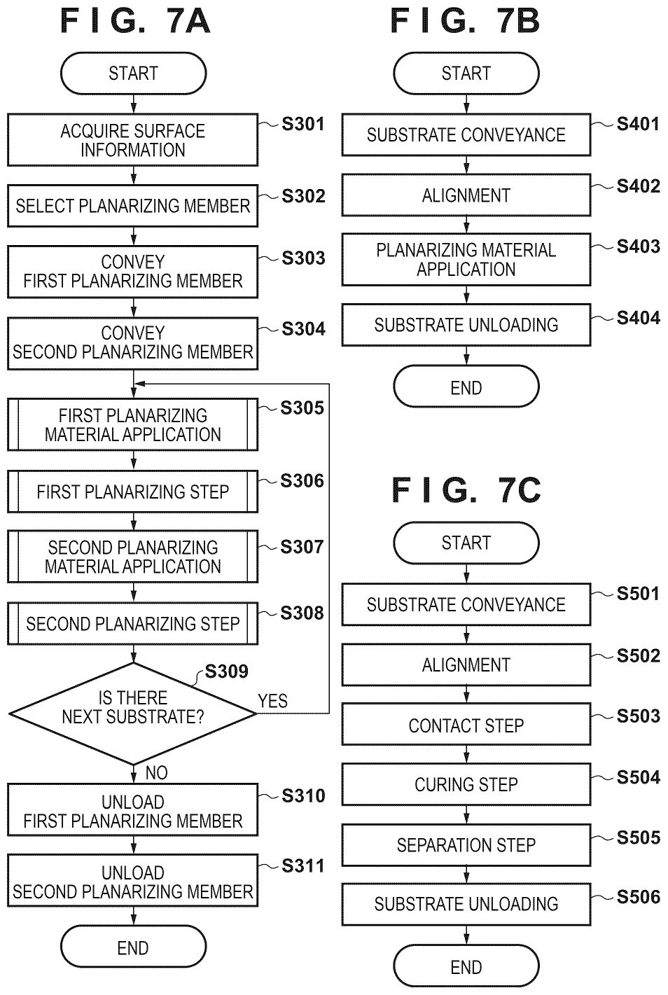

FIG. 7A is a flowchart illustrating the procedure of a planarizing method executed by the planarizing apparatus 200 according to the second embodiment. In step S301, the controller CU acquires surface information of each of the plurality of planarizing members 2. In step S302, the controller CU determines the first planarizing member as the planarizing member 2 used in the first planarizing step and the second planarizing member as the planarizing member 2 used in the second planarizing step (determination step). The determination method can comply with the first embodiment.

In step S303, the controller CU controls the conveyance mechanism to convey, to the planarizing member holder 32 of the planarizing unit PU1, the planarizing member 2 determined as the first planarizing member in step S302, thereby causing the planarizing member holder 32 to hold the planarizing member 2. In step S304, the controller CU controls the conveyance mechanism to convey, to the planarizing member holder 32 of the planarizing unit PU2, the planarizing member 2 determined as the second planarizing member in step S302, thereby causing the planarizing member holder 32 to hold the planarizing member 2. In step S305, the controller CU causes the application unit MU to perform an application step of applying the planarizing material to the substrate 1 to form the first planarizing layer. The application step can include steps S401 to S404 shown in a flowchart of FIG. 7B.

In step S401, the controller CU controls the conveyance mechanism to convey the substrate 1 to the substrate holder 21 of the application unit MU. In step S402, the controller CU measures the alignment mark of the substrate 1 using the alignment unit 24, and positions the substrate 1. In step S403, the controller CU applies the planarizing material onto the substrate by the application unit 23 while moving the substrate 1 by the substrate driver 22. The application distribution of the planarizing material can be determined based on the pattern density of the substrate 1 and the like. In step S404, the controller CU unloads the substrate 1 from the application unit MU by the conveyance mechanism.

In step S306, the controller CU controls the respective components of the planarizing unit PU1 to perform the first planarizing step. The first planarizing step can include steps S501 to S506 shown in a flowchart of FIG. 7C. In step S501, the conveyance mechanism is controlled to convey the substrate 1 applied with the planarizing material to the substrate holder 31 of the planarizing unit PU1. In step S502, the controller CU aligns the substrate 1 by observing the alignment mark on the substrate 1 using the alignment unit 37. Steps S503, S504, and S505 are a contact step, a curing step, and a separation step, respectively, and are the same as steps S204, S205, and S206 of the first embodiment, respectively, and a description thereof will be omitted. In step S506, the controller CU controls the conveyance mechanism to unload the substrate 1.

In step S307, the controller CU causes the application unit MU to perform an application step of applying the planarizing material to the substrate 1 to form the second planarizing layer. The application step can include steps S401 to S404 described above. In step S308, the controller CU controls the respective components of the planarizing member 2 to perform the second planarizing step. The second planarizing step can include steps S501 to S506 described above. In step S309, the controller CU determines whether there is the substrate 1 to be processed next. If there is the substrate 1 to be processed next, the controller CU executes step S305 for the substrate 1. If there is no substrate 1 to be processed next, the controller CU advances to step S310. In step S310, the controller CU controls the conveyance mechanism to unload the planarizing member 2 as the first planarizing member from the planarizing member holder 32 of the planarizing unit PU1. In step S311, the controller CU controls the conveyance mechanism to unload the planarizing member 2 as the second planarizing member from the planarizing member holder 32 of the planarizing unit PU2.

Note that for the sake of simplicity, in FIG. 7A, steps S305, S306, S307, and S308 are sequentially executed, but execution of a process including steps S305 and S306 may be started for the new substrate simultaneously with step S308.

According to the second embodiment, as compared to the first embodiment, the productivity is improved by providing the plurality of planarizing units.

### <Article Manufacturing Method>

The article manufacturing method to which the planarizing apparatus and the planarizing method according to each of the first and second embodiments are applied will be exemplarily described below. The article manufacturing method can include a planarizing step of forming a planarizing film on a surface of a substrate, a pattern forming step of forming a pattern on the planarizing film by a photolithography step, and a processing step of obtaining an article by processing the substrate on which the pattern has been formed. In the planarizing step, a planarizing film including the first planarizing layer and the second planarizing layer can be formed by the planarizing apparatus and the planarizing method according to each of the first and second embodiments. The pattern forming step can include, for example, a step of applying a photoresist film onto the planarizing film, and a step of forming a latent image on the photoresist film by transferring the pattern of an original to the photoresist film using an exposure apparatus. The pattern forming step can further include a step of converting the latent image into a physical pattern by developing the photoresist film. The processing step can include, for example, a step of etching, using the physical pattern, a structure under the pattern.

The planarizing film formed in the planarizing step may permanently form at least part of each of various kinds of articles, or may be temporarily formed when manufacturing each of various kinds of articles. An article is, for example, an electric circuit element, an optical element, MEMS, a recording element, or a sensor. Examples of the electric circuit element are volatile or nonvolatile semiconductor memories such as a DRAM, an SRAM, a flash memory, and an MRAM, and semiconductor elements such as an LSI, a CCD, an image sensor, and an FPGA.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-064118, filed Apr. 11, 2024, which is hereby incorporated by reference herein in its entirety.

What is claimed is:

1. A planarizing method comprising:
forming a first planarizing layer on a substrate by molding a curable composition using a first planarizing member;
forming a second planarizing layer on the first planarizing layer by molding the curable composition using a second planarizing member; and
determining, based on information representing performance of each of at least two planarizing members, a planarizing member to be used as the first planarizing member and a planarizing member to be used as the second planarizing member.

2. The method according to claim 1, wherein in the determining, a planarizing member having performance satisfying a predetermined criterion is determined as the second planarizing member, and a planarizing member having performance not satisfying the predetermined criterion is determined as the first planarizing member.

3. The method according to claim 2, wherein in the determining, a planarizing member having performance not satisfying the predetermined criterion but satisfying a criterion lower than the predetermined criterion is determined as the first planarizing member.

4. The method according to claim 1, wherein in the determining,
a planarizing member having performance satisfying a predetermined criterion is determined as the second planarizing member, and
one of a planarizing member having performance satisfying the predetermined criterion and a planarizing member having performance not satisfying the predetermined criterion is determined as the first planarizing member.

5. The method according to claim 2, wherein
each of the at least two planarizing members has a planarizing surface to be brought into contact with the curable composition, and
the predetermined criterion includes a criterion concerning a defect of the planarizing surface.

6. The method according to claim 1, wherein in the determining, the first planarizing member and the second planarizing member are determined so that performance of the second planarizing member is superior to performance of the first planarizing member.

7. The method according to claim 1, wherein the information includes information concerning a use count of each of the at least two planarizing members.

8. The method according to claim 1, wherein the information includes information concerning a manufacturing grade of each of the at least two planarizing members.

9. The method according to claim 1, wherein the information includes information concerning coating of each of the at least two planarizing members.

10. An article manufacturing method comprising:
forming a planarizing film on a substrate;
forming a pattern on the planarizing film by a photolithography step; and
obtaining an article by processing the substrate on which the pattern has been formed,
wherein in the forming of the planarizing film, a first planarizing layer and a second planarizing layer are formed by a planarizing method defined in claim 1.

11. A planarizing apparatus for forming a first planarizing layer on a substrate by molding a curable composition using a first planarizing member and forming a second planarizing layer on the first planarizing layer by molding the curable composition using a second planarizing member, comprising:
a controller configured to determine, based on information representing performance of each of at least two planarizing members, a planarizing member to be used as the first planarizing member and a planarizing member to be used as the second planarizing member.

12. The apparatus according to claim 11, wherein the controller determines, as the second planarizing member, a planarizing member having performance satisfying a predetermined criterion, and determines, as the first planarizing member, a planarizing member having performance not satisfying the predetermined criterion.

13. The apparatus according to claim 12, wherein the controller determines, as the first planarizing member, a planarizing member having performance not satisfying the predetermined criterion but satisfying a criterion lower than the predetermined criterion.

14. The apparatus according to claim 11, wherein
the controller determines, as the second planarizing member, a planarizing member having performance satisfying a predetermined criterion, and
the controller determines, as the first planarizing member, one of a planarizing member having performance satisfying the predetermined criterion and a planarizing member having performance not satisfying the predetermined criterion.

15. The apparatus according to claim 12, wherein
each of the at least two planarizing members has a planarizing surface to be brought into contact with the curable composition, and
the predetermined criterion includes a criterion concerning a defect of the planarizing surface.

16. The apparatus according to claim 11, wherein the controller determines the first planarizing member and the second planarizing member so that performance of the second planarizing member is superior to performance of the first planarizing member.

17. The apparatus according to claim 11, wherein the information includes information concerning a use count of each of the at least two planarizing members.

18. The apparatus according to claim 11, wherein the information includes information concerning a manufacturing grade of each of the at least two planarizing members.

19. The apparatus according to claim 11, wherein the information includes information concerning coating of each of the at least two planarizing members.

20. The apparatus according to claim 11, wherein the controller controls a processing procedure of a plurality of substrates so as to form the first planarizing layer on each of the plurality of substrates and then form the second planarizing layer on each of the plurality of substrates.

21. The apparatus according to claim 11, further comprising:
a first planarizing unit configured to form the first planarizing layer on each of a plurality of substrates; and
a second planarizing unit configured to form the second planarizing layer on each of the plurality of substrates.

22. An article manufacturing method comprising:
forming a planarizing film on a substrate;
forming a pattern on the planarizing film by a photolithography step; and
obtaining an article by processing the substrate on which the pattern has been formed,
wherein in the forming of the planarizing film, a first planarizing layer and a second planarizing layer are formed by a planarizing apparatus defined in claim 11.
